(19) United States
(12) Patent Application Publication
(10) Pub. No.: US 2006/0128119 A1
(43) Pub. Date: Jun. 15, 2006

(54) Semiconductor device fabrication method

(75) Inventors: Yasunobu Saito, Tokyo (JP); Toru Sugiyama, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/282,664

(22) Filed: Nov. 21, 2005

(30) Foreign Application Priority Data
Dec. 13, 2004 (JP) 2004-359801

(51) Int. Cl. H01L 21/78; H01L 21/461

(52) U.S. Cl. 438/460; 438/692

(57) ABSTRACT

According to the present invention, there is provided a semiconductor device fabrication method comprising: forming a circuit pattern of a semiconductor element and a ground pad connected to a ground interconnection of said circuit pattern, in a semiconductor chip region divided into a plurality of portions on a main surface of a semiconductor substrate; forming a separation groove in a separation region for separating a plurality of semiconductor chips; forming a metal film so as to cover the main surface of said semiconductor substrate; forming an insulating film so as to cover said metal film on the main surface of said semiconductor substrate and fill said separation groove; etching an entire surface of said insulating film to leave said insulating film behind on a bottom of said separation groove; forming a metal layer connected to said ground pad via said metal film, and extending to an upper end of said insulating film on the bottom of said separation groove; and polishing a back surface of said semiconductor substrate until the bottom of said separation groove is exposed, and cutting the semiconductor chip region from said separation groove, thereby separating said plurality of semiconductor chips.

### CROSS REFERENCE TO RELATED APPLICATION

This application is based upon and claims benefit of priority under 35 USC §119 from the Japanese Patent Application No. 2004-359801, filed on Dec. 13, 2004, the entire contents of which are incorporated herein by reference.

### BACKGROUND OF THE INVENTION

The present invention relates to a semiconductor device fabrication method.

It is well known that in a high-frequency semiconductor device, the parasitic inductance of an interconnection, particularly a ground interconnection, which connects the semiconductor device has influence on the high-frequency characteristics.

To solve this problem, a via hole structure in which a through hole is formed in a semiconductor substrate or a sidewall metallized structure in which a conductive metal layer connecting to a ground pad on the main surface of a semiconductor chip is formed on its side surface is used to connect the ground pad formed on the main surface of the semiconductor chip to the ground of a packing substrate.

The formation of the ground electrode in the via hole structure is advantageous in miniaturization, but complicates the process because it is necessary to perform, e.g., lithography to the back surface and the etching step for a hole formation. This is the cause of a decrease in yield.

On the other hand, the formation of the ground electrode in the sidewall metallized structure simplifies the process because it is unnecessary to perform any of lithography from the back surface, etching, and plating. Accordingly, a higher yield than that of the via hole structure can be expected.

Conventionally, the metallized structure is fabricated as follows. First, semiconductor elements, ground pads, and signal line pads are formed, and an insulating film having holes in portions of the surfaces of the ground pads and signal line pads and in dicing line regions is formed on the main surface of a semiconductor substrate.

Separation grooves are formed in the dicing line regions from the main surface side of the semiconductor substrate by a dicing apparatus.

Then, a feeder metal layer is formed on the main surface of the semiconductor substrate by using, e.g., Au/Ti. A photoresist film having exposure holes in regions including the ground pads and separation grooves formed on the main surface of the semiconductor substrate is formed, and Au plating is selectively performed.

The photoresist film is removed, and the extra feeder metal layer is etched away, thereby electrically connecting the ground pads and the plating layers in the separation grooves.

After that, the back surface of the semiconductor substrate is polished. As a consequence, the plating layers on the bottoms of the separation grooves are exposed. When polishing is further performed, individual semiconductor chips are separated. In this state, the side surfaces of each semiconductor chip are covered with the feeder metal layer and plating layer.

Since, however, the interior of each separation groove is entirely covered with the Au plating layer and feeder metal layer, these Au plating layer and feeder metal layer are also polished away when the back surface of the semiconductor substrate is polished, but it is difficult to simultaneously polish the hard and fragile semiconductor substrate and the soft and malleable Au. Consequently, unseparated Au sometimes remains on the bottoms of the separation grooves, and this poor separation sometimes decreases the yield.

To avoid poor separation of Au, it is also possible to perform selective plating so that the bottoms of the separation grooves are not covered with plating. For this purpose, however, a mask pattern matching the separation grooves must be formed. If this mask pattern is formed by exposure by using a general stepper, the mask pattern is highly likely to crack during exposure because separation grooves having a depth of about 100 μm are formed in the longitudinal and lateral directions on the surface of the semiconductor substrate.

Also, if exposure is performed by a contact exposure apparatus which produces relatively little stress, the possibility of cracking decreases, but the possibility of pattern misalignment increases. If this misalignment occurs, chips having unplated wall surfaces are produced, and this decreases the yield. If the width of each separation groove is increased to compensate for this misalignment, the yield similarly decreases.

A reference disclosing the technique concerning the conventional sidewall metallization is as follows.

Japanese Patent Laid-Open No. 2001-244284

### SUMMARY OF THE INVENTION

According to one aspect of the invention, there is provided a semiconductor device fabrication method comprising:

forming a circuit pattern of a semiconductor element and a ground pad connected to a ground interconnection of said circuit pattern, in a semiconductor chip region divided into a plurality of portions on a main surface of a semiconductor substrate;

forming a separation groove in a separation region for separating a plurality of semiconductor chips;

forming a metal film so as to cover the main surface of said semiconductor substrate;

forming an insulating film so as to cover said metal film on the main surface of said semiconductor substrate and fill said separation groove;

etching an entire surface of said insulating film to leave said insulating film behind on a bottom of said separation groove;

forming a metal layer connected to said ground pad via said metal film, and extending to an upper end of said insulating film on the bottom of said separation groove; and

polishing a back surface of said semiconductor substrate until the bottom of said separation groove is exposed, and cutting the semiconductor chip region from said separation groove, thereby separating said plurality of semiconductor chips.

According to one aspect of the invention, there is provided a semiconductor device fabrication method comprising:

forming a circuit pattern of a semiconductor element and a ground pad connected to a ground interconnection of said circuit pattern, in a semiconductor chip region divided into a plurality of portions on a main surface of a semiconductor substrate;

forming a separation groove in a separation region for separating a plurality of semiconductor chips;

forming a metal film so as to cover the main surface of said semiconductor substrate;

forming an insulating film so as to cover said metal film on the main surface of said semiconductor substrate and fill said separation groove;

etching an entire surface of said insulating film to leave said insulating film behind on a bottom of said separation groove;

forming a photoresist film having a hole in a region including at least said separation groove, and having a desired shape;

forming a metal layer connected to said ground pad via said metal film, and extending to an upper end of said insulating film on the bottom of said separation groove, by using said photoresist film as a mask; and

polishing a back surface of said semiconductor substrate until the bottom of said separation groove is exposed, and cutting the semiconductor chip region from said separation groove, thereby separating said plurality of semiconductor chips.

### BRIEF DESCRIPTION OF THE DRAWINGS

FIG. 1 is a longitudinal sectional view of elements in a predetermined step of a semiconductor device fabrication method according to the first embodiment of the present invention;

FIG. 2 is a longitudinal sectional view of elements in a predetermined step of the semiconductor device fabrication method according to the first embodiment;

FIG. 3 is a longitudinal sectional view of elements in a predetermined step of the semiconductor device fabrication method according to the first embodiment;

FIG. 4 is a longitudinal sectional view of elements in a predetermined step of the semiconductor device fabrication method according to the first embodiment;

FIG. 5 is a longitudinal sectional view of elements in a predetermined step of the semiconductor device fabrication method according to the first embodiment;

FIG. 6 is a longitudinal sectional view of elements in a predetermined step of the semiconductor device fabrication method according to the first embodiment;

FIG. 7 is a longitudinal sectional view of elements in a predetermined step of the semiconductor device fabrication method according to the first embodiment;

FIG. 8 is a longitudinal sectional view of elements in a predetermined step of the semiconductor device fabrication method according to the first embodiment;

FIG. 9 is a longitudinal sectional view of elements in a predetermined step of the semiconductor device fabrication method according to the first embodiment;

FIG. 10 is a longitudinal sectional view of elements in a predetermined step of a semiconductor device fabrication method according to a comparative example;

FIG. 11 is a longitudinal sectional view of elements in a predetermined step of a semiconductor device fabrication method according to the comparative example;

FIG. 12 is a longitudinal sectional view of elements in a predetermined step of a semiconductor device fabrication method according to the comparative example;

FIG. 13 is a longitudinal sectional view of elements in a predetermined step of a semiconductor device fabrication method according to a second embodiment of the present invention;

FIG. 14 is a longitudinal sectional view of elements in a predetermined step of the semiconductor device fabrication method according to the second embodiment;

FIG. 15 is a longitudinal sectional view of elements in a predetermined step of the semiconductor device fabrication method according to the second embodiment; and

FIG. 16 is a longitudinal sectional view of elements in a predetermined step of the semiconductor device fabrication method according to the second embodiment.

### DETAILED DESCRIPTION OF THE INVENTION

Embodiments of the present invention will be described below with reference to the accompanying drawings.

### (1) FIRST EMBODIMENT

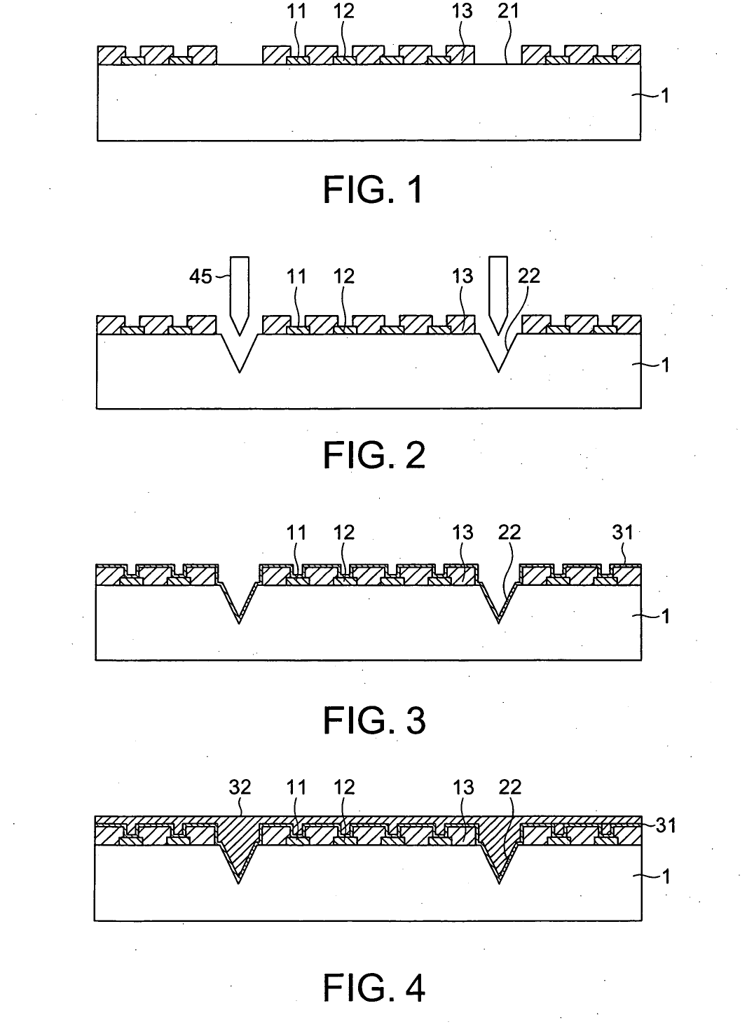

A semiconductor device fabrication method according to the first embodiment of the present invention will be explained below with reference to FIGS. 1 to 9 each showing a longitudinal sectional view of elements in a predetermined step.

As shown in FIG. 1, in a semiconductor chip region divided into a plurality of sections on the main surface of a semiconductor substrate 1, circuit patterns as semiconductor elements and ground pads 11 and signal line pads 12 made of a metal film such as Au are formed.

After that, an insulating film 13 having holes in portions of the surfaces of the ground pads 11 and signal line pads 12 and in dicing line regions 21 is formed on the main surface of the semiconductor substrate 1. The dicing line regions 21 are separation regions for separating the semiconductor device into individual semiconductor chips.

As shown in FIG. 2, separation grooves 22 having a depth of, e.g., 100 μm are formed in the dicing line regions 21 from the main surface side of the semiconductor substrate 1 by using blades 45 of a dicing apparatus. In this case, the sectional shape of the sidewalls of each separation groove 22 is formed into a forward mesa shape by the use of the blade 45 having a V-shaped blade tip.

As shown in FIG. 3, a feeder metal layer 31 about 100 mm thick made of Au/Ti is formed on the entire main surface of the semiconductor substrate 1. Subsequently, as shown in FIG. 4, an insulating film 32 made of, e.g., a photoresist or SOG is formed by coating. In this state, the thickness of the insulating film 32 in the separation grooves 22 is large.

Then, the whole surface of the insulating film 32 is etched back by O₂ RIE or the like.

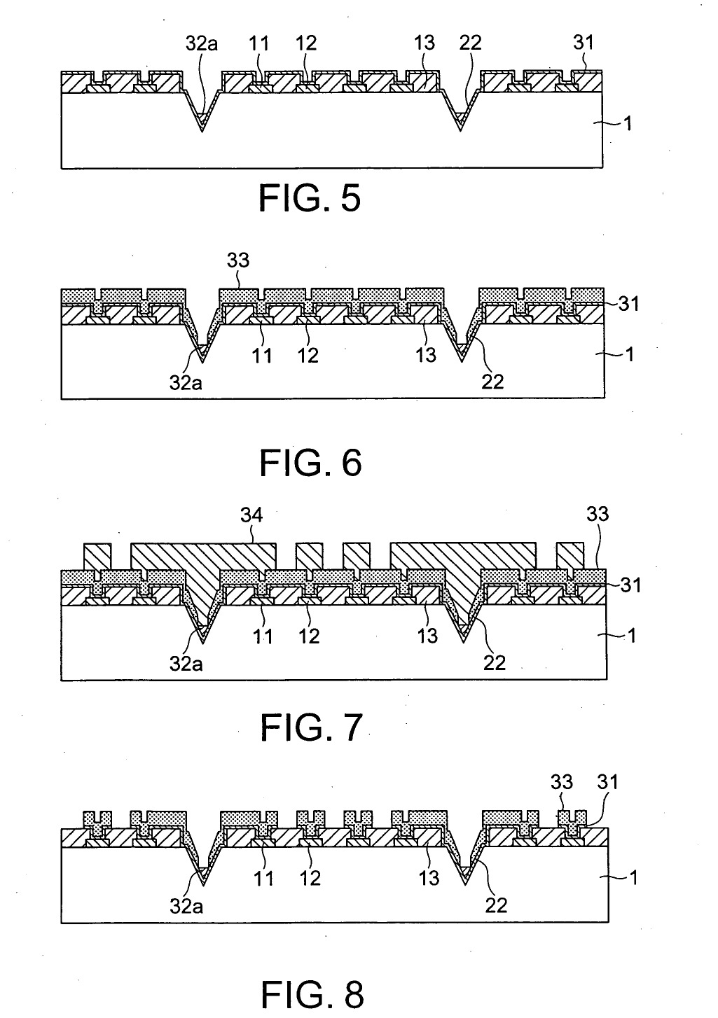

As shown in FIG. 5, when the insulating film 32 is etched until the insulating film 32 on the main surface of the semiconductor substrate 1 is completely removed, an insulating film 32a remains on the bottom of each separation groove 22 since the thickness of the insulating film 32 in the separation groove 22 is large.

Then, as shown in FIG. 6, an Au plating layer 33 is formed on the semiconductor main surface by electroplating.

It is important that in this state, the bottom of each separation groove 22 is not plated because the insulating film 32a remains.

As shown in FIG. 7, a photoresist film 34 is so formed as to cover the ground pads 11, the Au plating layers in the separation grooves 22, and the signal pads 12, and unnecessary portions of the Au plating layer 33 and feeder metal layer 31 are etched away.

As shown in FIG. 8, the ground pads 11 and the Au plating layers 33 in the separation grooves 22 are electrically connected, and no Au plating layer 33 remains on the bottom of each separation groove 22.

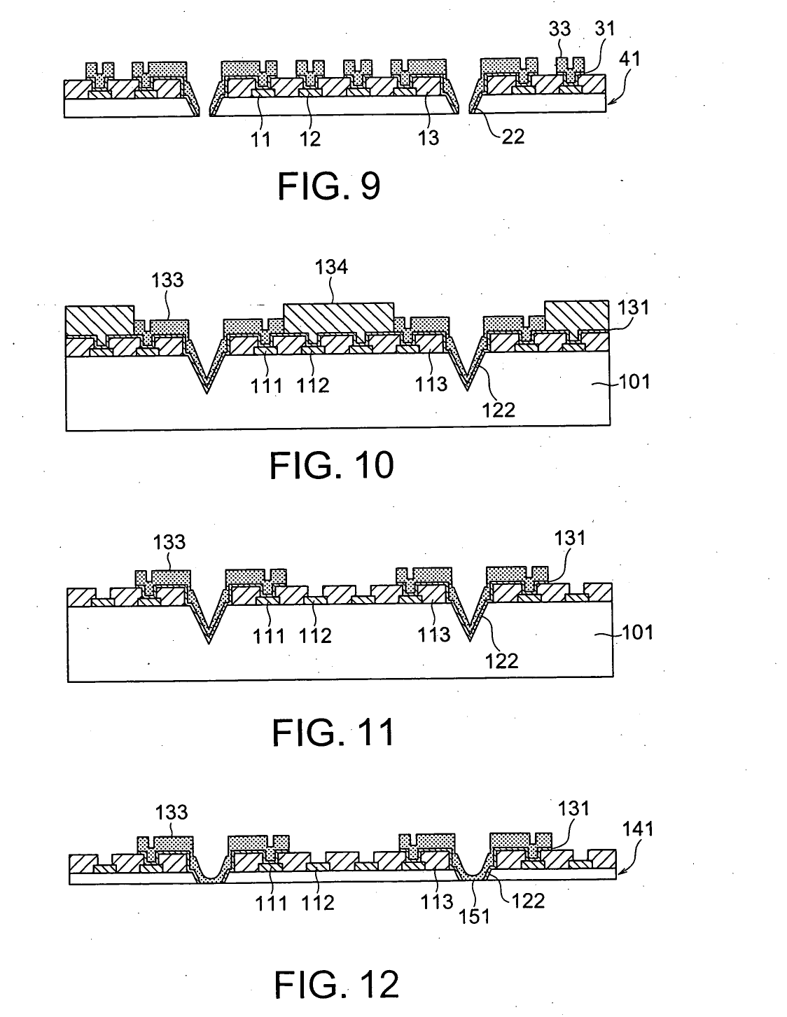

When the back surface of the semiconductor substrate 1 is polished after that, the Au plating layer 33 or feeder metal layer 31 on the bottom of each separation groove 22 is exposed. When polishing is further performed, as shown in FIG. 9, individual semiconductor chips 41 are separated.

In this state, not the Au plating layer 33 but the thin feeder metal layer 31 alone exists on the bottom of each separation groove 22. Therefore, separation by polishing is easily and reliably performed, so poor separation occurring in the conventional devices as described above does not occur.

The upper portions of the side surfaces of each separated semiconductor chip 41 are covered with the feeder metal layer 31 and Au plating layer 33, and the lower portions of the side surfaces are made of the semiconductor layer alone.

A method of fabricating a sidewall metallized structure as a comparative example will be explained below with reference to FIG. 10.

This method is the same as the first embodiment described above from the step shown in FIG. 1 to the step shown in FIG. 3, so an explanation thereof will be omitted.

Until the step shown in FIG. 3, a feeder metal layer 131 is formed on the main surface of a semiconductor substrate 101.

Then, as shown in FIG. 10, a photoresist film 134 having holes in regions including ground pads 111 and separation grooves 122 formed on the main surface of the semiconductor substrate 101 is formed, and an Au plating layer 133 is selectively formed by electroplating.

After the photoresist film 134 is removed, an extra feeder metal layer 131 is etched away. As a consequence, as shown in FIG. 11, the ground pads 111 and the Au plating layers 133 in the separation grooves 122 are electrically connected.

When the back surface of the semiconductor substrate 101 is polished after that, as shown in FIG. 12, the Au plating layer 133 or feeder metal layer 131 on the bottom of each separation groove 122 is exposed. When polishing is further performed, individual semiconductor chips 141 are separated.

In this comparative example, however, each separation groove 122 is entirely covered with the Au plating layer 133 and feeder metal layer 131. Therefore, the Au plating layer 133 and feeder metal layer 131 are also polished away when the back surface of the semiconductor substrate 101 is polished. As described earlier, however, it is difficult to simultaneously polish the hard and fragile semiconductor substrate 101 and the soft and malleable Au plating layer 133. Accordingly, as shown in FIG. 12, unseparated portions of the Au plating layer 133 remain, and this poor separation decreases the yield.

By contrast, in the first embodiment described previously, the insulating film 32a remains on the bottom of each separation groove 22 in the step shown in FIG. 5. When plating is performed in this state as shown in FIG. 6, no Au plating layer 33 is formed and the thin feeder metal layer 31 alone exists on the bottom of each separation groove 22. Since, therefore, separation by polishing is easily and reliably performed, poor separation as in the comparative example can be prevented.

### (2) SECOND EMBODIMENT

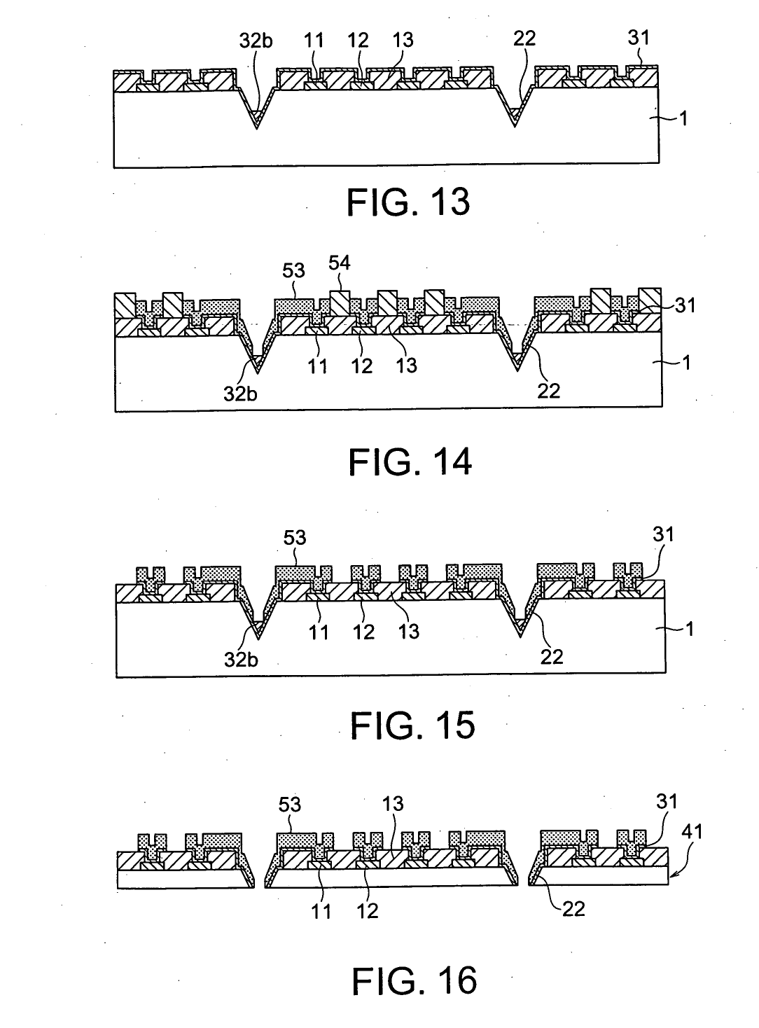

A semiconductor device fabrication method according to the second embodiment of the present invention will be explained below with reference to FIGS. 13 to 16.

The second embodiment differs from the first embodiment in the order of formation of a photoresist film and Au plating layer.

As shown in FIG. 13, an insulating film 32b is left behind on the bottom of each separation groove 22 following the same procedures as in the first embodiment shown in FIGS. 1 to 5.

After that, the insulating film 32b left behind on the bottom of each separation groove 22 is made sparingly soluble so as not to dissolve in a photoresist which is applied later. For example, if the insulating film 32b is a photoresist made of, e.g., a novolak-based resin, it is made sparingly soluble by CF₄/O₂ plasma processing.

The use of a photoresist as the insulating film 32b is advantageous in that the existing apparatus can be used. However, if the insulating film 32b left behind on the bottom is not a photoresist but a material, such as SOG (Spin On Glass), which does not mix in the photoresist to be applied later, the step of making the insulating film 32b sparingly soluble is unnecessary.

Then, as shown in FIG. 14, a photoresist film 54 having exposure holes in regions including ground pads 11 and the separation grooves 22 formed on the main surface of a semiconductor substrate 1 is formed, and an Au plating layer 53 is selectively formed by electroplating.

In this state, the insulating film 32b remains on the bottom of each separation groove 22, so the bottom of the separation groove 22 is not plated.

The photoresist film 54 is then removed, and an extra feeder metal layer 31 covered with the photoresist film 54 is etched away. Consequently, as shown in FIG. 15, the ground pads 11 and the Au plating layers 53 in the separation grooves 22 are electrically connected, and no Au plating layer 53 exists on the bottom of each separation groove 22.

When the back surface of the semiconductor substrate 1 is polished after that, as shown in FIG. 16, the Au plating layer 53 or feeder metal layer 31 on the bottom of each separation groove 22 is exposed. When polishing is further performed, individual semiconductor chips 41 are separated.

In the second embodiment, as in the first embodiment described above, the insulating film 32a remains on the bottom of each separation groove 22. When plating is performed in this state, no Au plating layer 53 is formed and the thin feeder metal layer 31 alone exists on the bottom of each separation groove 22. Accordingly, separation by polishing is easily and reliably performed, and poor separation can be prevented.

The semiconductor device fabrication methods of the above embodiments can prevent a decrease in yield caused by poor separation.

Each of the above embodiments is merely an example and does not limit the present invention. Therefore, these embodiments can be variously modified within the technical scope of the present invention. For example, the materials and etching methods of, e.g., the insulating film, feeder metal layer, and plating layer and the process of making the photoresist film sparingly soluble are not limited to those of the above embodiments, and other materials and methods may also be used.

What is claimed is:

1. A semiconductor device fabrication method comprising:
forming a circuit pattern of a semiconductor element and a ground pad connected to a ground interconnection of said circuit pattern, in a semiconductor chip region divided into a plurality of portions on a main surface of a semiconductor substrate;
forming a separation groove in a separation region for separating a plurality of semiconductor chips;
forming a metal film so as to cover the main surface of said semiconductor substrate;
forming an insulating film so as to cover said metal film on the main surface of said semiconductor substrate and fill said separation groove;
etching an entire surface of said insulating film to leave said insulating film behind on a bottom of said separation groove;
forming a metal layer connected to said ground pad via said metal film, and extending to an upper end of said insulating film on the bottom of said separation groove; and
polishing a back surface of said semiconductor substrate until the bottom of said separation groove is exposed, and cutting the semiconductor chip region from said separation groove, thereby separating said plurality of semiconductor chips.

2. A method according to claim 1, further comprising, after said circuit pattern and ground pad are formed, forming another insulating film having holes in at least a portion of a surface of said ground pad and in the separation region.

3. A method according to claim 1, wherein said metal film is a feeder metal film made of Au/Ti.

4. A method according to claim 1, wherein said insulating film is one of a photoresist film made of a novolak-based resin and an SOG (Spin On Glass) film.

5. A method according to claim 1, wherein when the entire surface of said insulating film is to be etched, etching is performed until said insulating film on the main surface of said semiconductor substrate is completely removed.

6. A method according to claim 1, wherein when said metal layer is to be formed, a plating layer is formed by electroplating the main surface of said semiconductor substrate such that a portion of the bottom of said separation groove where said insulating film exists is not plated.

7. A method according to claim 2, wherein when said metal layer is to be formed, a plating layer is formed by electroplating the main surface of said semiconductor substrate such that a portion of the bottom of said separation groove where said insulating film exists is not plated.

8. A method according to claim 1, wherein after said metal layer is formed, said metal film and metal layer in a region except for said separation groove are patterned such that said metal film and metal layer in said separation groove remain.

9. A method according to claim 2, wherein after said metal layer is formed, said metal film and metal layer in a region except for said separation groove are patterned such that said metal film and metal layer in said separation groove remain.

10. A semiconductor device fabrication method comprising:
forming a circuit pattern of a semiconductor element and a ground pad connected to a ground interconnection of said circuit pattern, in a semiconductor chip region divided into a plurality of portions on a main surface of a semiconductor substrate;
forming a separation groove in a separation region for separating a plurality of semiconductor chips;
forming a metal film so as to cover the main surface of said semiconductor substrate;
forming an insulating film so as to cover said metal film on the main surface of said semiconductor substrate and fill said separation groove;
etching an entire surface of said insulating film to leave said insulating film behind on a bottom of said separation groove;
forming a photoresist film having a hole in a region including at least said separation groove, and having a desired shape;
forming a metal layer connected to said ground pad via said metal film, and extending to an upper end of said insulating film on the bottom of said separation groove, by using said photoresist film as a mask; and
polishing a back surface of said semiconductor substrate until the bottom of said separation groove is exposed, and cutting the semiconductor chip region from said separation groove, thereby separating said plurality of semiconductor chips.

11. A method according to claim 10, wherein
said insulating film is a photoresist film made of a novolak-based resin, and
after being left behind on the bottom of said separation groove, said insulating film is made sparingly soluble by CF₄/O₂ plasma processing.

12. A method according to claim 10, wherein said insulating film is an SOG (Spin On Glass) film.

13. A method according to claim 10, further comprising, after said circuit pattern and ground pad are formed, forming another insulating film having holes in at least a portion of a surface of said ground pad and in the separation region.

14. A method according to claim 10, wherein said metal film is a feeder metal film made of Au/Ti.

15. A method according to claim 10, wherein when the entire surface of said insulating film is to be etched, etching is performed until said insulating film on the main surface of said semiconductor substrate is completely removed.

16. A method according to claim 10, wherein when said metal layer is to be formed, a plating layer is formed by electroplating the main surface of said semiconductor substrate such that a portion of the bottom of said separation groove where said insulating film exists is not plated.
